(19) United States
(12) Patent Application Publication
(10) Pub. No.: US 2013/0015875 A1
(43) Pub. Date: Jan. 17, 2013

(54) FAILURE DETECTION SYSTEM FOR PHOTOVOLTAIC ARRAY

(71) Applicant: Arun Kumar, Ann Arbor, MI (US)

(72) Inventor: Arun Kumar, Ann Arbor, MI (US)

(73) Assignee: United Solar Ovonic LLC, Auburn Hills, MI (US)

(21) Appl. No.: 13/181,602

(22) Filed: Jul. 13, 2011

(51) Int. Cl. G01R 31/26

(52) U.S. Cl. 324/761.01

(57) ABSTRACT

A process for detecting and terminating a fault in a photovoltaic device is provided that operates in the millisecond or faster timescale. A process includes measuring a current or voltage in each of a plurality of strings relative to a common rail. When the voltage or current from a string is outside a predetermined threshold, a flag is generated indicating the presence of a fault in the string. A control unit will detect the flag and disconnect the faulty string from the system through a switch. The use of continuously rolling averages of baseline currents and voltages as well as a series of measurements averaged to measure the difference of current or voltage at each step provides a process and a fault detection system that does not suffer from false fault detections thereby providing a reliable and efficient system for detecting and terminating faults in photovoltaic devices.

### FIELD OF THE INVENTION

The invention is related to fault detection in photovoltaic devices. More specifically, the invention is related to arc or other fault detection and suppression of subsequent thermal events relating to a defective photovoltaic device string.

### BACKGROUND OF THE INVENTION

Demand for electrical energy continues to rise due to the introduction of new electrical devices and increased use of climate control systems. Traditional fossil fuel generation is limited by supply issues and is constantly subject to price fluctuations due to market conditions. Alternative energy sources are, therefore, in expanding demand. Solar energy represents a plentiful and virtually inexhaustible source or electrical power. There is great desire for improved solar generation devices useful for household and industrial solar electricity generation.

Photovoltaic arrays made of strings of photovoltaic cells must be supported by a high degree of safety. Of equal importance is maintaining a reliable source of electrical energy that is resistant to total system failure due to unavoidable thermal expansion and other external events illustratively from impacts. Photovoltaic arrays are placed so as to gather the maximum amount of incident light. These locations are commonly also exposed to thermal differences and are at risk of impacts from the surrounding environment. These perils increase the risk of physical decay that could lead to electrical faults in the arrays. Photovoltaic devices typically include a number of panels connected in series whose combined voltage reaches up to 1 kV DC or more. Compromised laminate insulation or broken leads, under certain conditions, can result in exposed DC voltage of a few hundred volts with respect to the grounded substrate. This exposed source of electric energy can combine with water from dew/rain or debris collected near the array to create a dangerous electric arc. A photovoltaic string subjected to such electric arcing will continually feed the arc as there is typically is no fuse or circuit breaker in current path, and the continued sun exposure maintains the string in a fully energized state.

A system of preventing damage from ground faults has been proposed. U.S. Pat. No. 6,593,520 teaches a system where each string of solar cells is divided into substrings. Each substring is separated by a switch. When a ground fault is detected, a switch is opened disconnecting the faulty string, or substring, from the remainder of the system. This system has many drawbacks including that the system is limited to detection of ground faults leaving other types of fault either undetected or uncorrected. Additionally, the faulty substring will continue to remain fully powered as long as it is exposed to sufficient light energy such that the fault will continue unabated until a user intervenes. This does not adequately prevent physical damage that may result from the fault.

U.S. Pat. No. 6,101,073 teaches a system for shutting down an entire solar array if a ground fault is detected. This system requires a detection threshold with low sensitivity to prevent erroneous detection and unwanted shutdown. Thus, this system suffers from poor ability to quickly and effectively detect faults such as arc faults and effectively prevent possible damage resulting from the fault.

The prior systems are incapable of effectively detecting multiple fault types with the speed and sensitivity necessary for effective control of fault induced damage, and to simultaneously allow a photovoltaic array to continue to function should a fault be present in a portion of the system. Thus, there is a need for methods and systems for effective detection and isolation of faults in photovoltaic systems.

### SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

Processes and systems are provided for detecting and mitigating a fault in a string of photovoltaic cells. Processes involve comparisons between an electrical parameter (e.g. current differences or voltages) from a string that may or may not be subject to a fault and the electrical parameter from an array of strings. A process may include determining an electrical parameter difference that is the difference in string electrical parameter from a single string and the average of the average electrical parameter of all strings in an array. When an electrical parameter difference is outside a predetermined threshold value, a fault is detected in the string. A flag is optionally generated indicative of the present or the absence of a fault in the string. Average string electrical parameters are optionally calculated for each individual string for a time t. Optionally, 10 or more measurements of string electrical parameters are made in time t. An electrical parameter difference is optionally calculated by subtracting the average array electrical parameter from the average string electrical parameter. The process optionally includes generating a flag indicative of the status of the string if the electrical parameter difference is outside a predetermined threshold value, optionally 0.15 amperes for current difference, or optionally 0.7 volts for voltage. Determining an electrical parameter difference is optionally repeated for a time t.

The processes optionally repeats the determination of the presence or absence of a fault for each of n strings in an array of strings thereby optionally checking for a fault over the entire array of strings. When a string is found normal such as in the absence of a detected fault, the processes optionally include applying a voltage to a transistor that serves as a switch thereby maintaining the electrical connection of the string to the remainder of the array. Should a fault be detected in one or more strings, an alarm is optionally engaged so as to alert a user or the system of the presence of the fault thereby facilitating repair.

As a method of preventing false detection, the measuring of a string electrical parameter is optionally repeated sequentially until a time t is reached. The time t is optionally less than 100 ms, optionally 6 ms or less. In some embodiments, the number of strings n is 12 or fewer, optionally 6 or fewer.

Also provided is a system for the detection and optionally mitigation of a fault in a photovoltaic device. A system includes: a first detector electrically associated with a string of one or more photovoltaic cells, the first detector capable of measuring an electrical parameter at the negative end of the string; a second detector electrically associated with the string and capable of measuring the electrical parameter at the positive end of the string; a control unit electrically connected to the first detector and the second detector, the control unit capable of detecting the presence or absence of an abnormality in one or more of said strings; and a switch for each string that is positionable to an open state when the control unit detects an abnormality in said string, whereby the open state electrically disconnects the string from the photovoltaic device. An alarm is optionally provided producing a signal when the control unit identifies an abnormality (e.g. fault) in one or more strings. The system is optionally used with a photovoltaic device that includes a plurality of strings of one or more photovoltaic cells. The number of strings is optionally 12, optionally 6.

An abnormality in a string is optionally a current difference outside a predetermined current threshold value that is optionally 0.15 amperes. An abnormality is optionally a voltage difference outside a predetermined voltage threshold value that is optionally 0.7 volts.

In some embodiments, a switch is a field effect transistor. The switch is optionally located at the negative terminus of the string. To further prevent backfeeding of current to a fault, one or more strings optionally includes a reverse flow preventative diode that is optionally located proximal to the positive terminus of the string.

### BRIEF DESCRIPTION OF THE DRAWINGS

FIG. 1 is a flow diagram illustrating one embodiment of a fault detection process with (A) illustrating one embodiment of a start up process; (B) illustrating one embodiment of a process of establishing baseline measurements; (C) illustrating one embodiment of a detection sequence; and (D) illustrating one embodiment of a reset sequence;

FIG. 2 is a depiction of one embodiment of a photovoltaic device associated with a fault detection system;

FIG. 3 is a depiction of the termination of an arc fault by one embodiment of a fault detection system operating using an inventive process of detecting faults.

### DETAILED DESCRIPTION OF EMBODIMENTS OF THE INVENTION

The following description of particular embodiment(s) is merely exemplary in nature and is in no way intended to limit the scope of the invention, its application, or uses, which may, of course, vary. The invention is described with relation to the non-limiting definitions and terminology included herein. These definitions and terminology are not designed to function as a limitation on the scope or practice of the invention but are presented for illustrative and descriptive purposes only.

The invention has utility as a process and system for the detection, isolation, and suppression of a fault in a photovoltaic string. The processes and systems provide rapid and sensitive, yet reliable detection of a fault such as a ground fault or an arc fault. The process detects a fault within one or more of a plurality of strings where a string includes one or more photovoltaic cells connected in series.

A process includes detecting one or more differences in an electrical parameter between a single string and the remainder of the strings in a photovoltaic array electrically associated with the string of interest. In some embodiments, a difference in an electrical parameter is determined between a string and a common rail to which all strings in an array are electrically connected. An electrical parameter difference that is at or outside a predetermined threshold value will generate a flag that may be used to signal a disconnection of the affected string from the remainder of the system. This method allows for disengagement of the affected string from the system while also allowing the remainder of the strings to continue producing electrical energy.

A flag is optionally recorded in a memory of a detection system if a fault is detected or if a fault is not detected depending on the user's desired system output. In some embodiments, when a fault is detected, a flag is generated indicating the presence of the fault in the string. As such, the presence of a flag optionally indicates the presence of a fault for the purposes of the inventive method. The description provided herein is directed to a flag indicative of a fault for exemplary purposes alone. It is equally appreciated that a flag is optionally generated in the absence of a fault such that when the detection system checks the memory for the presence of a flag, its absence indicates a fault. As such, the generation of a flag is equally appreciated to be operable for the recording a fault or recording the absence of a fault.

As used herein, a string includes one or more a photovoltaic cells capable of generating electrical energy in the presence of incident light of an appropriate wavelength and intensity. In some embodiments, a string includes a single photovoltaic cell. Optionally, a string includes a plurality of photovoltaic cells connected in series. The number of photovoltaic cells included in a single string is not limited by the invention. Optionally, a string includes 1, 2, 3, 4, 5, 6, 7, 8, 9, 10, 11, 12, 13, 14, 15, 16, 17, 18, 19, 20, or more photovoltaic cells.

In some embodiments, the number of photovoltaic cells connected in series in a single string is capable of producing up to 600 volts (V) direct current (DC). In some embodiments, the number of photovoltaic cells connected in series in a single string is capable of producing up to 1 kV DC. It is appreciated that the maximum combined voltage is optionally in excess of 1 kV DC such that the invention is not limited by the maximum voltage generated by a string.

A string is optionally a member of a photovoltaic array. A photovoltaic array is a plurality of strings electrically associated in parallel. The number of strings in an array is not limited. In some embodiments, the number of strings is 12. Optionally, the number of strings is 6. Optionally, the number of strings in an array is from 2 to 24, or any value or range therebetween.

An electrical parameter is optionally current difference or voltage. As used herein the term “electrical parameter” is optionally substituted with “current difference” or “voltage” depending on whether a current is used for fault detection, or voltage is used for fault detection. As such, an electrical parameter difference is optionally a difference in current difference between a string and an array, a voltage difference between a string an array, or both. In determining an electrical parameter difference where the electrical parameter is current difference, some embodiments calculate a difference in the current difference of a string and the average array current difference, which is the average of the string current differences of all strings in an array that the subject string is a member, or to a common rail to which all strings in the array are electrically connected. Optionally, in the measurement of an electrical parameter, some embodiments analyze a voltage difference between the voltage in a string string and an average array voltage which is the average of the sting voltages of all strings in an array that the subject sting is a member, or to a common rail to which all strings in the array are electrically connected.

In embodiments where an electrical parameter is a current difference, a current difference is determined that includes measuring a string current difference in a string, determining an array current difference, and calculating the difference between the string current difference and the array current difference. An array current difference is optionally determined by averaging the string current differences from all strings connected to a rail or otherwise present in a photovoltaic device. A current difference optionally represents the absolute value of the difference of the string current difference and the array current difference such that if the current in the string is higher or lower than the current in the rail, the absolute value of the current difference, optionally expressed as the current output, will be useful as a singular measure of current difference relative to a predetermined current threshold for the detection of the presence or absence of a fault.

In some embodiments, an electrical parameter is voltage. A voltage difference is optionally determined by measuring a string voltage from a string, measuring a rail voltage in a rail electrically connected to the string, and calculating the voltage difference between the string voltage and the rail voltage. A voltage difference optionally represents the absolute value of the calculated voltage difference, optionally expressed as the voltage output, such that if the voltage in the string is higher or lower than the voltage in the rail, the absolute value of the voltage difference will be useful as a singular measure of voltage difference relative to a predetermined threshold for the detection of the presence or absence of a fault.

Both a voltage difference and a current difference are optionally determined. Illustratively, a voltage difference and a current difference are determined simultaneously or sequentially. As such, either a voltage difference or a current difference that is outside a predetermined threshold will indicate the presence of a fault in a string.

In some embodiments, a flag is generated that is indicative of the presence or absence of a fault. Optionally, a flag is generated in the presence of a fault such as when an electrical parameter difference is outside a predetermined threshold value. Optionally, a flag is generated in the absence of a fault such as when the electrical parameter difference is between a predetermined threshold value and zero.

Measuring an electrical parameter is optionally performed at any location within a string. Optionally, a string is electrically connected to or associated with one or more detectors for measuring an electrical parameter. A detector is optionally connected to or associated with one or more positions on a string depending on the desired electrical parameter to be detected and the type of detector employed. Optionally, a current is detected by a detector associated with a single location on a string. Optionally, a string current is detected at two positions within or surrounding a string. In some embodiments, a first current detector is placed at the beginning (negative end) of a string and a second current detector is placed at the end (positive end) of a string such that any change in current within the string is measured as a difference between current in and current out. Optionally, a voltage is detected by a detector connected at two locations within a string. In some embodiments, a detector is connected upstream and downstream of one or more photovoltaic cells within the string. Optionally, a detector is connected upstream and downstream of all the photovoltaic cells in the string. In some embodiments, a detector is connected to a string at or in proximity to a reverse flow preventative diode.

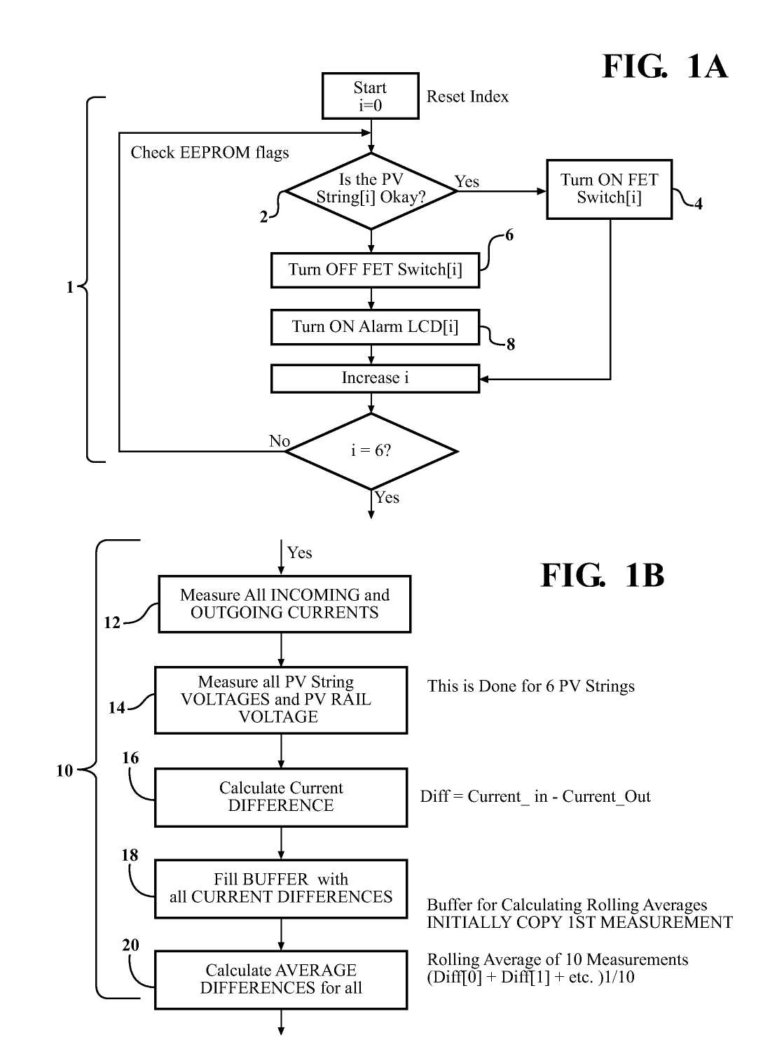

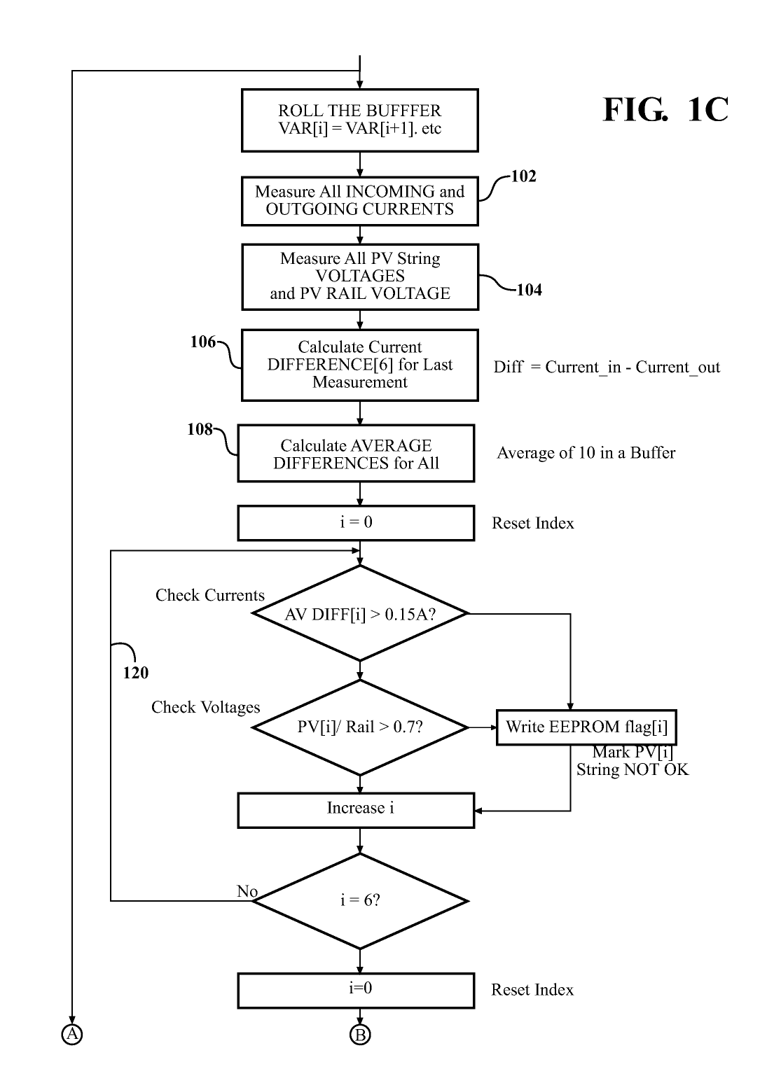

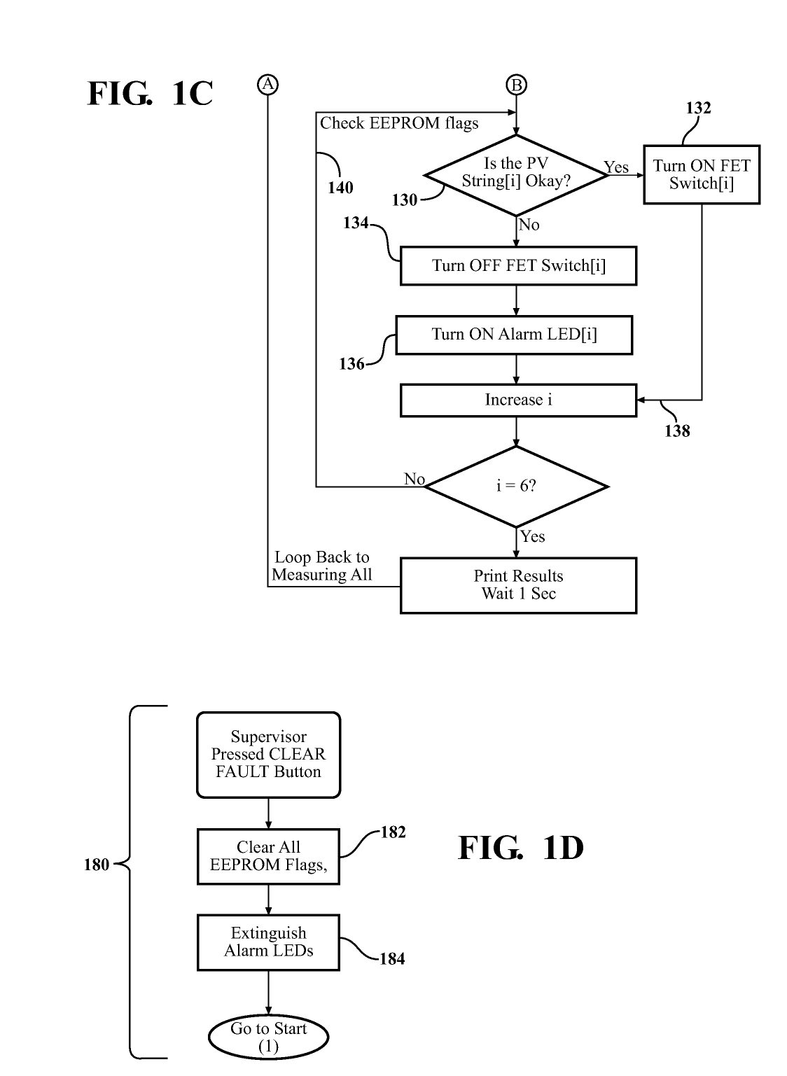

One embodiment of a method of detecting a fault in a photovoltaic device including six strings is presented in FIG. 1. It is appreciated that the number of strings is not limited by the inventive process. The number of strings presented in the figures and the description is for illustrative purposes alone. FIG. 1A illustrates an inventive process including a startup sequence 1 that serves as a check to prevent a prior uncorrected fault from continuing to create a damage or injury risk. As seen in FIG. 1A, a startup sequence 1 optionally includes a check 2 of all the strings present in the system by verification that a flag is or is not present in the system memory, optionally EEPROM (Electrically Erasable Programmable Read-Only Memory), that indicates the presence of a fault. If no fault is recorded in the memory by the presence or absence of a flag, the system turns on (closes) a switch 4 that allows operation of the associated string. In the event that a prior fault is uncleared from the system by the presence or absence of a flag, the switch remains or is put in the off (open) configuration 6 preventing operation of the effected string. An alarm 8 is optionally engaged to indicate to an operator that a fault exists. Upon checking whether any prior faults are recorded in the system memory for a first string, the process proceeds to check the current operational state of all strings present in the system. Only strings that do not have a prerecorded fault in the memory are able to be used to generate electrical energy.

The startup sequence 1 of FIG. 1A is illustrated to include a series of individual checks in series for exemplary purposes alone. It is appreciated that two or more strings may be checked for prior faults in the memory simultaneously or sequentially. In some embodiments, the checks 2 are performed simultaneously for all strings in the system.

As shown in FIG. 1B, an inventive process optionally includes determination of one or more baseline measurements 10. Baseline measurements are optionally used for comparison with or calculation of current differences or voltage differences to detect the presence or absence of a fault in one or more strings. A baseline measurement is an array current difference, an array voltage, or both. In some embodiments, all incoming and outgoing currents in each of n strings are measured 12 as string current differences in a string. In some embodiments, the voltage of all strings is measured and the voltage of a rail is measured 14. The string current differences are calculated as the current in minus the current out. A buffer is present that is capable of being used for calculating rolling averages of string current differences and voltage differences to act as a baseline. The buffer is then occupied with the string current differences for all strings in the array 18. In some embodiments, the average of each of the string current differences or voltage differences is calculated over b measurements. The average provides a stable relative baseline for determination of subsequent current or voltage differences that are continuously updated during operation of a system. This provides array current differences and voltages that are independent on or change with the level of incident sunlight generating the currents and voltages in the array. When the level of incident light increases or decreases thereby increasing or decreasing the possible current and voltage generated by a photovoltaic string, the string current or voltages rises or falls accordingly. By maintaining a rolling average, a string current difference or a string voltage can be effectively compared to a reliable baseline.

The number of measurements b used to determine a baseline is any number at or greater than one. In an exemplary embodiment as depicted in FIG. 1, b is 10. The number of measurements to determine a baseline is optionally, 2, 3, 4, 5, 6, 7, 8, 9, 10, 11, 12, 13, 14, 15, or more.

As depicted in FIG. 1C detection of a fault includes a detection sequence 100. A detection sequence 100 includes determining an electrical parameter for a string and for the array, optionally measured at a rail. Illustratively, a process includes determining a current difference as an electrical parameter. A current difference for a string is determined by measuring optionally an average string current difference produced by a single string 102, determining an average array current difference 104, which is the average of the average string current differences from all strings or the average of the string current differences from all strings, and calculating the difference 106 between the average string current difference and the average array current difference.

An average string current difference for a single string is calculated by averaging the string current differences for a time t or a number of measurements m. A string current difference for a single string is optionally calculated by subtracting the current out (e.g. current at positive end of the string) from the current in (e.g. negative end string current). Each string current difference is optionally stored in a buffer. A second string current difference is optionally calculated by the same procedure and is then stored in the buffer. The string current difference is repeated m times for a time tᵢ (optionally equal to t) and each string current difference is stored in the buffer. Following m measurements, or time tᵢ, the string current differences are optionally averaged 108 to generate an average string current difference. The calculation of an average string current difference provides increased sensitivity for the detection of a fault while simultaneously preventing a false fault detection due to a single measurement not representative of the overall status of the string possibly due to a temporary fluctuation in the system. The value m is any value calculatable by a detector within a time tᵢ. Illustratively, tᵢ is less than 100 milliseconds (ms), optionally, less than 90, 80, 70, 60, 50, 40, 30, 20, 10, 9, 8, 7, 6, 5, 4, 3, 2, 1 ms or less. In some embodiments, tᵢ is between 2 and 10 ms. Optionally, tᵢ is 5-6 ms.

An average array current difference is then calculated by averaging the average string current differences for all strings in the photovoltaic array (optionally exclusive of the string subjected to fault detection), or in some embodiments by averaging the string current differences for all strings in the photovoltaic array. The average array current difference is then optionally stored in a buffer. A current difference for a string is then determined optionally by subtracting the average string current difference for the string from the average array current difference.

In some embodiments, a detection sequence 100 includes determining a voltage difference. A voltage difference is determined by measuring a string voltage produced by a string or a portion thereof 102, measuring a rail voltage 110 in a rail electrically connected to the string, and calculating the voltage difference 112 between the string and the rail. Optionally, a rail voltage is not directly measured but is the average of all voltages produced by all strings in an array in which the string of interest is a member, optionally exclusive of the string of interest. The voltage difference is optionally calculated by subtracting the voltage present in the rail from the voltage generated by the string. The voltage difference 112 calculated is then optionally stored in a buffer. A second voltage difference is optionally calculated by the same procedure and is then stored in the buffer. Calculating a voltage difference is then optionally repeated x times for a time tᵥ (optionally equal to t) and each calculated voltage difference is stored in the buffer. Following x measurements, or time tᵥ, the calculated voltage differences are optionally averaged 118 to generate an average calculated voltage difference. The calculation of an average calculated voltage difference provides increased sensitivity for the detection of a fault while simultaneously preventing a false fault detection due to a single measurement that is not representative of the actual string voltage or due to a temporary fluctuation in the system. The value x is appreciated to be any value calculatable by a detector within a time tᵥ. Illustratively, tᵥ is less than 100 ms, optionally, less than 90, 80, 70, 60, 50, 40, 30, 20, 10, 9, 8, 7, 6, 5, 4, 3, 2, 1 millisecond or less. In some embodiments, tᵥ is between 2 and 10 ms. Optionally, tᵥ is 5-6 ms.

Each of the electrical parameter differences is then checked by the detection system to determine if the differences are outside a predetermined threshold value. A predetermined threshold value may be user adjustable, may be fixed within the system, or may be adjusted by the system depending on characteristics of the environment or the photovoltaic array. In some embodiments, the average string current differences for each string are optionally compared to the average array current difference optionally by subtracting the average array current difference from the average string current difference to generate a current difference. If the current difference is outside a predetermined current threshold, a flag is stored in the system memory indicating the presence of a fault in the string.

Optionally, each of the calculated voltage differences is checked by the detection system to determine if the differences are outside a predetermined voltage threshold value. A predetermined voltage threshold value may be user adjustable, may be fixed within the system, or may be adjusted by the system depending on characteristics of the environment or the photovoltaic array. In some embodiments, the average voltages for each string are then optionally compared to the average array voltage optionally by subtracting the average array voltage from the string voltage or average string voltage. If the voltage difference is outside a predetermined voltage threshold, a flag is stored in the system memory indicating the presence of a fault in the string.

A predetermined current threshold value is optionally 0.15 amperes (A). A predetermined voltage threshold is optionally 0.7 V.

The process of optionally checking the current differences or optionally checking the voltage differences is then repeated 120 for each of the strings in the photovoltaic system by integers of i until i is equal to the number of strings in the system. FIG. 1 illustrates a system with 6 strings. The process of checking is repeated until i=6 in this embodiment. If the number of strings is 12, then the process is repeated until i=12.

A process optionally includes checking for the presence or the absence of a flag recorded in the system memory. For each string, the system checks the memory for the presence or absence of a flag 130. If a flag is absent (when a flag indicates a fault), the switch is closed (or maintained closed). In the event a flag is present (when a flag indicates a fault) the switch is opened 134. The process of checking for the presence or absence of a flag is then repeated 140 for each of the strings in the photovoltaic system until the presence or absence of a flag for each string is checked. When the checking indicates the presence of a fault, an alarm is optionally engaged 136 to alert a user to the presence of the fault.

After checking all strings, an inventive process optionally includes printing the results. Printing the results is optionally printing to the system memory in electronic form that is optionally then readable by a user through an interface, or printing to a hard copy. After the results of checking all strings is complete, a time is elapsed (optionally 1 second) and the detection sequence 100 is repeated. The detection sequence is repeated 100 as long as the photovoltaic system remains operational.

A switch is illustrated herein as a FET switch for exemplary purposes alone. It is appreciated that other switches known in the art are optionally used in a process or system of the invention. A switch is optionally placed upstream (negative end) of the first photovoltaic device in a string so that the entire string is optionally turned on or off by a single switch.

An alarm is optionally engaged upon detection of a fault in the system. An alarm is optionally audible, visible, kinesthetic, or combinations thereof. Optionally, an alarm is associated with a photovoltaic system or is remote from the system and is accessed by a remote connection illustratively wired or wireless.

If a fault is detected in the system, a user optionally activates a reset process 180 illustratively as depicted in the embodiment of FIG. 1D. A reset process optionally includes a user clearing all flags from the system 182, and optionally extinguishing all alarms 184. This is optionally accomplished by pressing one or more reset buttons that clears any flags from the memory. The fault detection process optionally then returns to the startup process 1. As such, the presence of a fault such as an arc fault, a ground fault, other fault, or combinations thereof results in disconnection of the defective string from the remainder of the system and alerts a user to the presence of the fault. A user can then correct the fault or choose to allow the string to remain inactive. By providing a switch for each string that is independently controllable by the system in response to the presence or absence of a fault, the single string may be turned completely off while allowing all other strings to remain active in the generation of electrical energy. This system also prevents damage that may occur due to the presence of the fault by turning off the string such that it is no longer capable of generating electrical energy preventing continuous fault presence and possible damage.

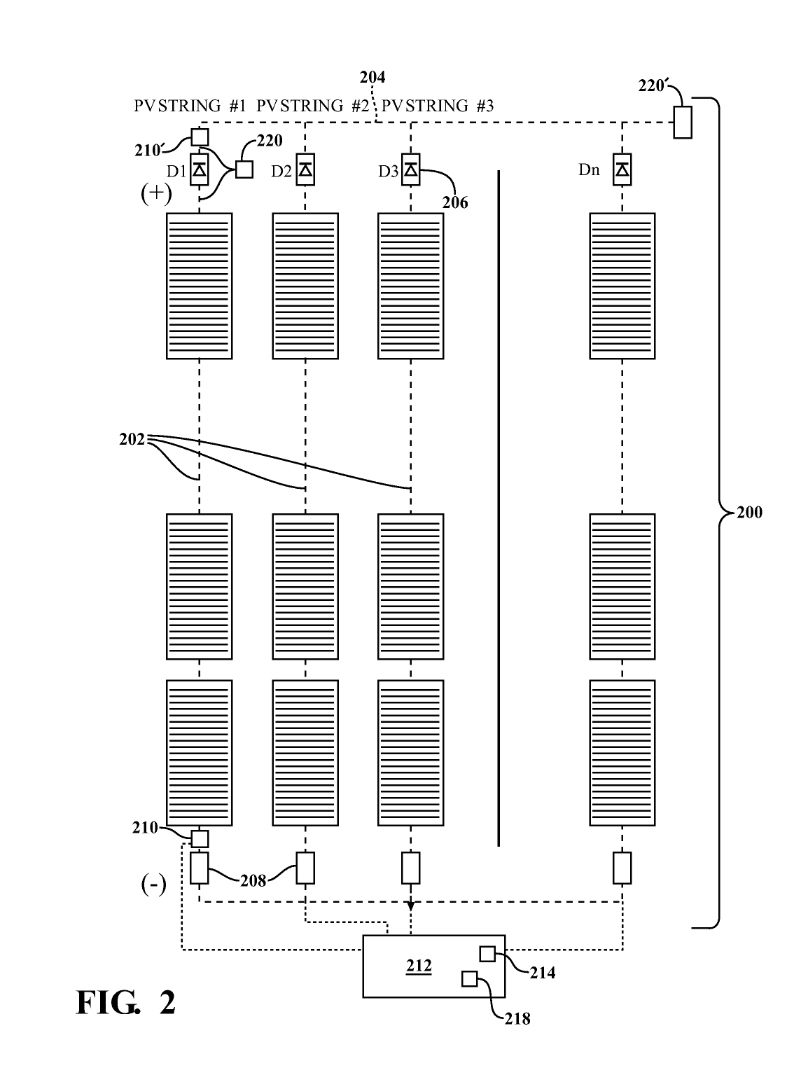

Also provided is a fault detection system for use with a photovoltaic device (e.g. array). A fault detection system is optionally capable of using a process of the present invention to detect the presence or absence of a fault within an associated photovoltaic system. An exemplary photovoltaic system is illustrated in FIG. 2. A photovoltaic system 200 includes n strings 202 of photovoltaic cells connected in series. The number of strings or number of cells is not limited by the fault detection system. The number of strings n is one or more. In some embodiments, n is 6 or more. In some embodiments, n is 12. Each of the strings 202 includes a positive end and a negative end. The positive ends of all of n strings are electrically connected to a single rail 204. It is appreciated that a rail is optionally a conductive material that connects all strings and conducts a current and has a voltage representative of the entire photovoltaic system. A rail is optionally a combiner box, such as those known in the art whereby the positive terminals of each string are electrically connected to the combiner box that then conducts a current and has a voltage representative of the entire photovoltaic system.

Each string 202 includes a reverse flow preventative diode 206 that serves to prevent current flow in two directions thereby maintaining the positive and negative ends of each string. An illustrative example of a reverse flow preventative diode is a 6FR80 Vishay rectifier available from Vishay Intertechnology, Malvern, Pa. A diode 206 prevents flow from strings generating more current and passing through a rail from back flowing through strings generating less current due to differential positioning relative to a shadow or other block creating uneven light intensity over a plurality of strings. The presence of a diode 206 also serves to prevent reverse current flow in the event of a fault in a particular string thereby preventing current from normal strings from feeding a fault.

Each string illustratively includes a switch 208. A switch 208 is optionally positioned at the negative terminal of a string (e.g. near the ground common). A switch is positionable or engagable in a closed condition such that electric current can pass through a switch, or is in an open condition that prevents current flow through the switch. In some embodiments, a switch 208 is a field effect transistor (FET) such as a metal-oxide-semiconductor field-effect transistor (MOSFET). A FET allows rapid adjustment between an open condition and a closed condition merely by the application of a voltage to the switch. This also allows rapid conversion from a closed condition to an open condition upon detecting a fault in a string associated with a switch. An illustrative example of a switch is a N-channel MOSFT transistor (FCA47N60F, available from Fairfield Semiconductor, South Portland, Me.). A fault detection system includes one or more detectors 210 capable of measuring a current or a voltage of a string or a rail. A detector is optionally a clamp type current sensor clamped between a positive and negative portion of a string or a rail or a FET-type voltmeter connected between two points in a string or a rail. Other detector types are similarly operable. In some embodiments, a current detector is a current Hall-effect Sensor model ACS714 available from Allegro MicroSystems, Inc., Worcester, Mass. In some embodiments a voltage detector is a resistor divider available from Maxim-IC, Sunnyvale, Calif. (Model MAX186).

A fault detection system illustratively includes a first current detector associated with a string. A detector is associated if it is positioned in functional proximity to or directly connected to a current source (e.g. string, rail). A detector is optionally positioned at the beginning of the source, end of the source, or both, so as to be able to detect and quantify current flowing at the point of the detector or voltage. A first current 210 detector is capable of measuring the current upstream (negative end) of a string. Optionally, a first current detector 210 is positioned at or near the positive end of the string such that a fault within the string will occur upstream of the first current detector. Optionally, a first current detector 210 is positioned at or near the negative end of the string such that a fault within the string will occur downstream of the first current detector.

A second current detector 210′ is associated either with a rail that is electrically connected to a string or is connected to a string at the positive end (downstream) of the string. When the second current detector 210′ is associated with the rail, it is capable of measuring the current moving through the rail. When a second current detector 210′ is associated with a string at the positive end, the second current detector measures the outgoing current from the string. A second current detector is optionally positioned on the rail at a location allowing measurement of current representative of the plurality of n strings electrically attached to the rail.

A fault detection system illustratively includes a first voltage detector 220 electrically associated with a string. A voltage detector is associated if it is positioned in functional proximity to or directly connected to a current source (e.g. string, rail) so as to be able to detect and quantify voltage generated by or within the source. The first voltage detector 220 is capable of measuring the voltage generated by a string. Optionally, a first voltage detector 220 positioned at or near the positive end of the string, optionally in the proximity of a diode 206, such that a fault within the string will occur upstream of the first voltage detector.

A second voltage detector 220′ is optionally electrically associated with a rail that is electrically connected to the string. The second voltage detector 220′ associated with the rail is capable of measuring the voltage in the system at the rail. The second voltage detector 220′ is positioned on the rail at a location allowing measurement of voltage representative of the plurality of n strings electrically attached to the rail.

A control unit 212 is provided that is electrically connected to one or more detectors. The control unit serves to calculate differences in electrical parameters optionally between one or more strings 202 and a rail 204. The control unit optionally includes a memory buffer 214 that will store measurement values that can then be used to calculate differences in measurements, averages of current differences or voltage differences, and establish rolling baseline measurements of baseline currents and voltages or differences thereof. The control unit performs continuous measurements of string and rail voltages, currents, or both, to provide rapid detection and suppression of a fault. An alarm 218 is optionally associated with the control unit or is remote therefrom.

Each string optionally includes a one or more shunt resistors. The shunt resistor(s) serve to scale down the voltages of their associated string. In some embodiments, a shunt resistor is a resistor divider located in a rail voltage board. Optionally, a divider includes two resistors in parallel. A first resistor in a divider optionally is a 3MΩ HVC2512-3MFT18 Welwyn available from TT electronics plc, Weybridge, Surrey, England. A second resistor in a divider is optionally 10 kΩ 0.1% TNPW12061002BT9ET1-E3 available from Vishay, Malvern, Pa.

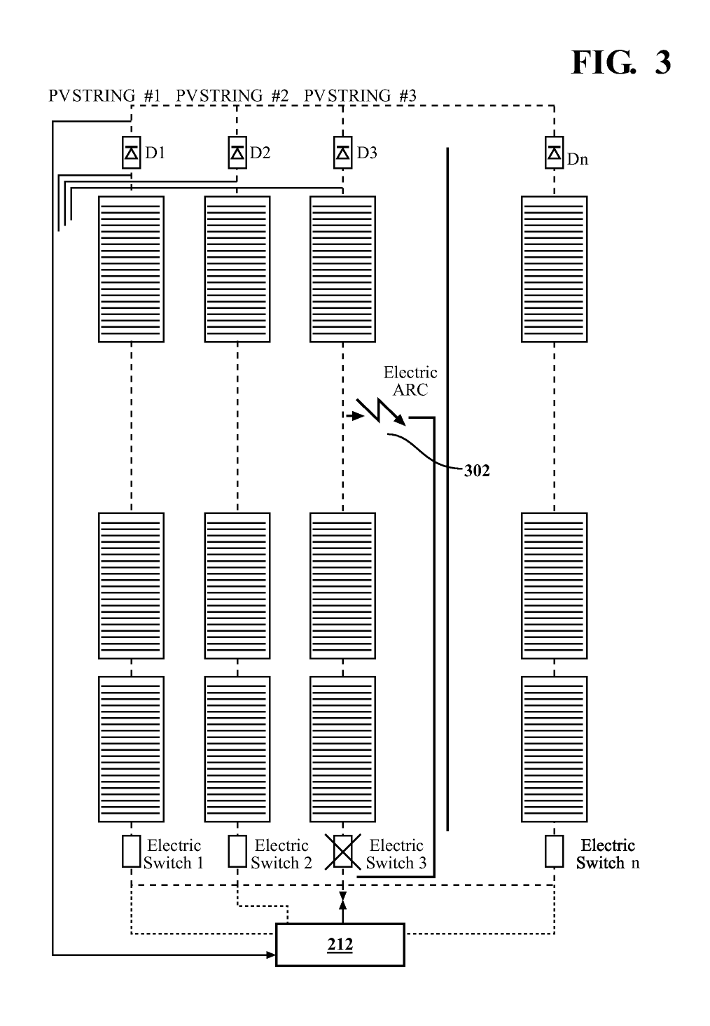

The operation of a fault detection system is illustrated in FIG. 3. In the presence of a fault 302 such as an arc fault, the current produced by the photovoltaic devices of the string is conducted to an alternate path outside the string. The arc current path can feedback upon the string. As long as the string is exposed to incident light, the current fed to the fault will continue to threaten injury or physical damage such as by fire. A fault detection system will detect a drop in current or voltage at the positive end of a string (e.g. string current difference is increased) relative to that of the other strings in the system or the rail where the drop is associated with a fault. When the drop in current or voltage is outside a predetermined threshold such as above or below a predetermined range from the rail voltage or array current difference, the control unit will cause a switch to open. In embodiments where a switch is a FET switch, the control unit will fail to apply a voltage to the FET switch thereby opening the circuit of the fault producing string. This both eliminates the ability of the arc or grounding to continue that is the cause of the fault as well as disconnects only the faulty string from the photovoltaic array such that the remainder of the system can continue to generate electrical power.

The fault detection systems and processes of detecting a fault provide the ability to detect and terminate an arcing or grounding in microsecond timescales while allowing the remainder of an array to continue to generate electrical energy from other strings in the system.

Various modifications of the present invention, in addition to those shown and described herein, will be apparent to those skilled in the art of the above description. Such modifications are also intended to fall within the scope of the appended claims.

It is appreciated that all reagents are obtainable by sources known in the art unless otherwise specified.

Patents and publications mentioned in the specification are indicative of the levels of those skilled in the art to which the invention pertains. These patents and publications are incorporated herein by reference to the same extent as if each individual application or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process of detecting a fault in a string of photovoltaic cells comprising:
determining an electrical parameter difference comprising:
(i) measuring a string electrical parameter in a string of one or more photovoltaic cells or a portion thereof;
(ii) determining an average array electrical parameter in an array of strings of photovoltaic cells electrically associated with said string; and
(iii) calculating said electrical parameter difference from said string electrical parameter and said array electrical parameter; and
detecting the presence or absence of a fault in said string, wherein a fault is detected when said electrical parameter difference is at or outside a predetermined threshold value.

2. The process of claim 1 further comprising generating a flag when said electrical parameter difference is at or outside said predetermined threshold value, said flag indicative of said fault.

3. The process of claim 1 further comprising opening a switch electrically connected to said string when said fault is detected.

4. The process of claim 1 further comprising repeating said step of measuring a string electrical parameter for a time t to produce an average string electrical parameter.

5. The process of claim 4 wherein said electrical parameter difference is calculated by determining the difference of said average string electrical parameter and said average array electrical parameter.

6. The process of claim 4 wherein t is 6 milliseconds or less.

7. The process of claim 4 wherein said measuring is performed ten or more times in time t.

8. The process of claim 1 wherein said electrical parameter is current difference.

9. The process of claim 1 wherein said electrical parameter is voltage.

10. The process of claim 1 further comprising repeating said step of determining an electrical parameter difference for each of n strings.

11. The process of claim 1 further comprising applying a voltage to a transistor associated with said string in the absence of a flag, said transistor operating as a switch.

12. The process of claim 1 further comprising engaging an alarm in the presence of said flag.

13. The process of claim 1 wherein said electrical parameter is current and said predetermined threshold value is 0.15 amperes.

14. The process of claim 1 wherein said electrical parameter is voltage and said predetermined threshold value is 0.7 volts.

15. The process of claim 1 further comprising repeating the process of claim 1 for a different electrical parameter.

16. A fault detection system for use with a photovoltaic device comprising:
a first detector electrically associated with a string of one or more photovoltaic cells, said string a member of a photovoltaic array of a plurality of strings, said first detector capable of measuring an electrical parameter at the negative end of said string;
a second detector electrically associated with said string, said second detector capable of measuring the electrical parameter at the positive end of said string;
a control unit electrically connected to said first detector and said second detector, said control unit capable of detecting the presence or absence of a fault in one or more of said strings; and
a switch for each string that is positionable to an open state when said control unit detects a fault in said string, said open state electrically disconnecting said string from said array.

17. The system of claim 16 wherein said abnormality is current difference for any one or more of said strings, said current difference outside a predetermined current threshold value.

18. The system of claim 16 wherein said abnormality is a voltage difference, said voltage difference at or above a predetermined voltage threshold value.

19. The system of claim 16 wherein said first detector and said second detector are capable of measuring said electrical parameter ten or more times in time t.

20. The system of claim 19 wherein t is 6 milliseconds or less.

21. The system of claim 16 further comprising one or more shunt resistors electrically associated with said string.
